(19) United States
(12) Patent Application Publication
(10) Pub. No.: US 2013/0168338 A1
(43) Pub. Date: Jul. 4, 2013

(54) SUPPORTING APPARATUS

(71) Applicants: KAI-MING LU, Tu-Cheng (TW); SHU-GANG SHI, Shenzhen City (CN)

(72) Inventors: KAI-MING LU, Tu-Cheng (TW); SHU-GANG SHI, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD, Shenzhen City (TW)

(21) Appl. No.: 13/477,088

(22) Filed: May 22, 2012

(30) Foreign Application Priority Data
Dec. 29, 2011 (CN) 201110450676.7

(51) Int. Cl. H01L 23/32

(52) U.S. Cl. 211/41.1

(57) ABSTRACT

A supporting apparatus includes a first pole, a second pole, a connecting pole, a reinforcing pole, and a fastener. A first end of the reinforcing pole is connected to a first end of the first pole. A first end of the connecting pole is connected to a second end of the first pole. A first end of the second pole is connected to a second end of the connecting pole. A second end of the reinforcing pole is connected to a middle of the first pole through the fastener. The connecting pole and the first pole each have a U-shaped cross-section. When the fastener is released from the first pole, the reinforcing pole is rotated to be received in the first pole. The reinforcing pole and the first pole are then rotated to be received in the connecting pole.

### BACKGROUND

1. Technical Field

The present disclosure relates to supporting apparatuses, and particularly, to a supporting apparatus for photovoltaic modules.

2. Description of Related Art

Supporting apparatuses for photovoltaic modules are usually made by welding a plurality of metal poles together with a non-flexible structure, which causes inconvenience in transportation of the supporting apparatuses.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an embodiment of a supporting apparatus.

FIG. 2 is an assembled, isometric view of the supporting apparatus of FIG. 1.

FIG. 3 is a using state view of the supporting apparatus of FIG. 2.

### DETAILED DESCRIPTION

The disclosure, including the accompanying drawings in which like references indicate similar elements, is illustrated by way of examples and not by way of limitation. It should be noted that references to “an” or “one” embodiment in this disclosure are not necessarily to the same embodiment, and such references mean at least one.

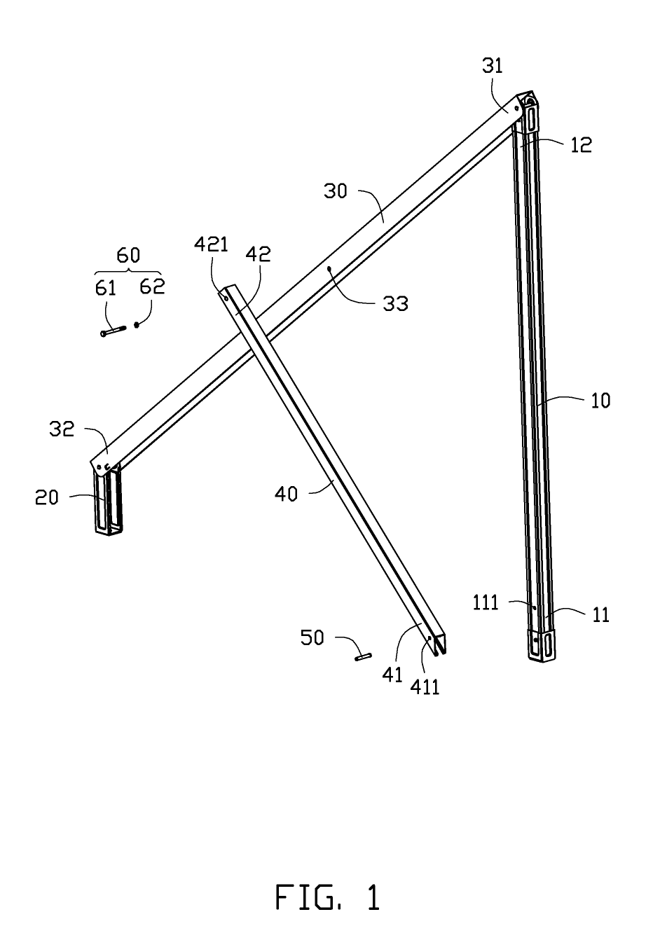

Referring to FIG. 1, an embodiment of a supporting apparatus includes a first pole 10, a second pole 20, a connecting pole 30, a reinforcing pole 40, a pivoting shaft 50, and a fastener 60. The first pole 10 and the second pole 20 each have a U-shaped cross-section.

The first pole 10 includes a first end 11 and a second end 12. The connecting pole 30 includes a first end 31 and a second end 32. The first end 31 is pivotably connected to the second end 12. The second end 32 is pivotably connected to a first end of the second pole 20.

The first pole 10 defines a pivot hole 111 near the first end 11. A mounting hole 33 is defined in a middle of the connecting pole 30.

The reinforcing pole 40 includes a first end 41 and a second end 42. The reinforcing pole 40 defines a first hole 411 near the first end 41 and a second hole 421 near the second end 42.

In the embodiment, the fastener 60 includes a bolt 61 and a nut 62 mating with the bolt 61.

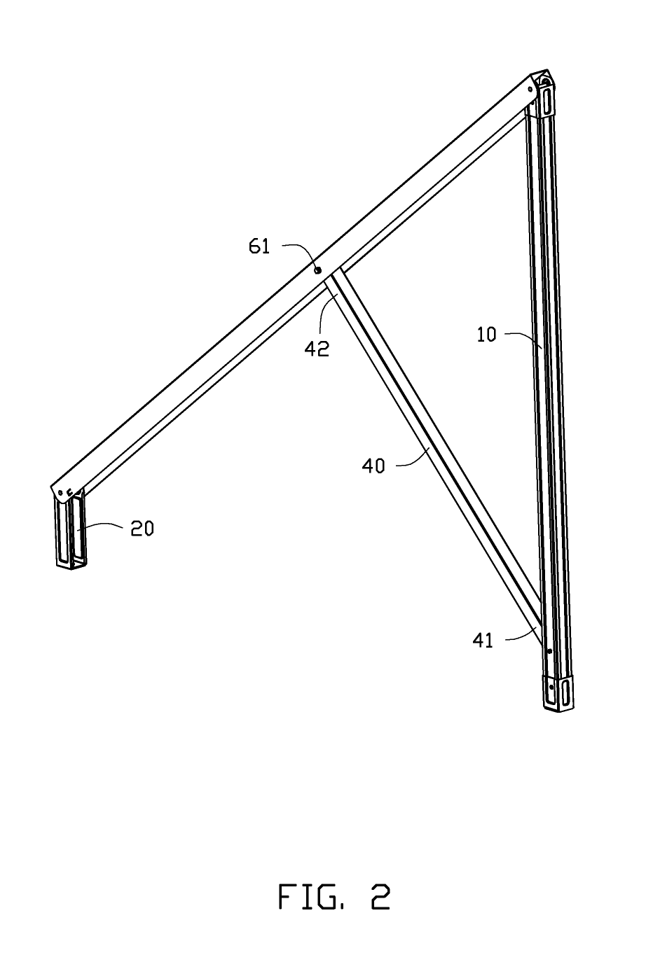

Referring to FIG. 2, in assembly, the first end 41 is pivotably connected to the first end 11 through the pivoting shaft 50 pivotably extending through the first end 41 and the pivot hole 111. The bolt 61 extends through the second hole 421 and the mounting hole 33 to screw into the nut 62, for mounting the second end 42 of the reinforcing pole 40 to the middle of the connecting pole 30.

In use, the first end 11 and a second end of the second pole 20 are fixed to a supporting flat (such as ground). Therefore the connecting pole 30 can be used to support the photovoltaic modules. Before the second pole 20 is fixed to the flat, the angle between the second pole 20 and the connecting pole 30 is adjustable, to adjust the angle of the connecting pole 30.

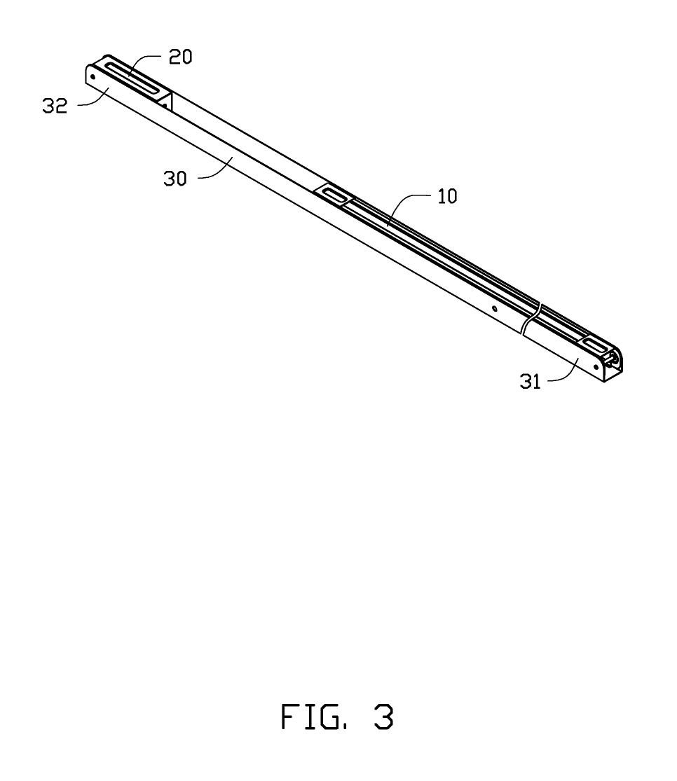

Referring to FIG. 3, when the fastener 60 is released, the reinforcing pole 40 is rotated to be received in the first pole 10. The first pole 10 together with the reinforcing pole 40 is then rotated to be received in the connecting pole 30. The second pole 20 is rotated to be received in the connecting pole 30. Therefore, the first pole 10, the second pole 20, and the reinforcing pole 40 are all received in the connecting pole 30, so the supporting apparatuses can be conveniently transferred.

It is to be understood, however, that even though numerous characteristics and advantages of the embodiments have been set forth in the foregoing description, together with details of the structure and function of the embodiments, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A supporting apparatus, comprising:
a first pole and a second pole each having a U-shaped cross section;
a connecting pole defining a mounting hole in a middle of the connecting pole;
a reinforcing pole; and
a fastener;
wherein a first end of the reinforcing pole is pivotably connected to a first end of the first pole, a first end of the connecting pole is pivotably connected to a second end of the first pole, a second end of the connecting pole is pivotably connected to a first end of the second pole, a second end of the reinforcing pole defines a through hole, the fastener extends through the through hole of the reinforcing pole and the mounting hole of the connecting pole, for mounting the second end of the reinforcing pole to the middle of the connecting pole; and
wherein when the fastener is released, the reinforcing pole is operable to be rotated to be received in the first pole, the first pole together with the reinforcing pole is then operable to be rotated and received in the connecting pole, the second pole is operable to be rotated and received in the connecting pole.

2. The supporting apparatus of claim 1, wherein the fastener comprises a bolt and a nut mating with the bolt, the bolt extends through the through hole of the reinforcing pole and the mounting hole of the connecting pole, to screw into the nut.
